(19) United States
(12) Patent Application Publication
(10) Pub. No.: US 2025/0218777 A1
(43) Pub. Date: Jul. 3, 2025

(54) SUPPRESSION OF DOPANT HYDRIDE EVOLUTION FROM EPITAXIAL FILMS IN INTEGRATED CIRCUIT (IC) MANUFACTURING

(71) Applicant: TEXAS INSTRUMENTS INCORPORATED, Dallas, TX (US)

(72) Inventors: Michael Todd, Lehi, UT (US); Tatsuya Tominari, Plano, TX (US)

(21) Appl. No.: 18/398,781

(22) Filed: Dec. 28, 2023

(51) Int. Cl. H01L 21/20; H01L 21/02; H01L 21/768

(52) U.S. Cl. CPC H01L 21/20; H01L 21/02576; H01L 21/0262; H01L 21/76865

(57) ABSTRACT

A method of fabricating an integrated circuit (IC) device is disclosed. A doped epitaxial layer may be formed over a substrate, including forming a surface-segregated layer (SSL) including a dopant species unincorporated in the doped epitaxial layer. Thereafter, the SSL may be removed in an in-situ operation, where a portion of the doped epitaxial layer may be removed based on removal selectivity.

### FIELD OF THE DISCLOSURE

Disclosed implementations relate generally to the field of integrated circuits (ICs) and IC fabrication. More particularly, but not exclusively, the disclosed implementations relate to an IC device including one or more doped epitaxial films that suppress dopant hydride evolution.

### BACKGROUND

Epitaxy is used in semiconductor fabrication to create a suitable crystalline foundation layer on which to build a semiconductor device, to deposit a crystalline film with engineered electrical properties, and/or to alter mechanical attributes of an underlayer in a way that improves its electrical conductivity. In some instances, an epitaxial layer can be doped during deposition by adding impurities to the source gas in order to obtain desired electrical properties of the epitaxial layer.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a method of fabricating an IC device is disclosed. The method may comprise, among others, placing a semiconductor substrate in a semiconductor process tool working volume; forming a doped epitaxial layer over the semiconductor substrate, including forming a surface-segregated layer (SSL) including a dopant species unincorporated in the doped epitaxial layer; removing the SSL; and removing the semiconductor substrate from the working volume. In some arrangements, the SSL may be removed using a selective etch process. In some arrangements, the SSL may be removed using a non-selective etch process.

In one example, an IC device is disclosed, which may comprise, among others, a semiconductor substrate; a doped epitaxial layer over the semiconductor substrate, the doped epitaxial layer having a first dopant concentration; and a surface conditioning layer over the doped epitaxial layer, the surface conditioning layer comprising silicon or germanium having a second dopant concentration less than the first dopant concentration.

In one example, an IC fabrication tool is disclosed, which may comprise, among others, at least one main chamber; a first processing chamber coupled to the at least one main chamber; and the first processing chamber configured to form a doped epitaxial layer over a substrate, where the first processing chamber may also be configured to remove a surface-segregated layer (SSL) formed over the doped epitaxial layer, where the SSL may include unincorporated dopant atoms. In a further variation, the IC fabrication tool may comprise a separate processing chamber (e.g., a second processing chamber) coupled to the at least one main chamber, where the second processing chamber may be configured to remove the SSL using a range of etch chemistries.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIGS. 1A and 1B depict flowcharts of an IC fabrication method according to some examples of the present disclosure;

FIG. 2 depicts a general schematic configuration of a wafer processing tool operable for epitaxial processing and suppression of dopant hydride evolution that may be deployed in association with one or more process stages of a wafer fabrication flow according to some examples of the present disclosure;

FIG. 3 depict representative chemical reactions illustrative of formation of a surface-segregated layer (SSL) including elemental dopants that may be generated in a doped epitaxy process in some examples; and

FIGS. 4A-4D depict cross-sectional views of an IC device at various stages of formation according to some examples of the present disclosure where dopant hydride evolution may be suppressed.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of IC devices having doped epitaxial films and techniques for suppression of dopant hydride evolution from a doped epitaxial film of an IC device are set forth below in the context of doped epitaxy using Group V dopants.

Epitaxy (prefix epi-means “on top of” and taxis means “ordered”) refers to a type of crystal growth or material deposition in which new crystalline layers are formed with one or more well-defined orientations with respect to an underlying substrate that may serve as a crystalline seed layer. The deposited crystalline film is called an epitaxial film or epitaxial layer. The relative orientation(s) of the epitaxial layer with respect to the seed layer may be defined in terms of the orientation of the crystal lattice of each material. For most epitaxial growths, the new layer is usually crystalline, with each crystallographic domain of an overlayer having a well-defined orientation relative to the substrate crystal structure. In general, single domain epitaxy, which is the growth of an overlayer crystal with one well-defined orientation with respect to the substrate crystal, is preferred.

One of the main commercial applications of epitaxial growth is in the semiconductor industry, where doped or undoped semiconductor films are grown epitaxially on a substrate having a specific crystalline orientation defined by its Miller index. Several epitaxial techniques are available for the fabrication of epitaxial layers comprising a variety of semiconductor materials, e.g., including but not limited to metalorganic vapor-phase epitaxy (MOVPE), liquid phase epitaxy (LPE), vapor phase epitaxy (VPE), molecular beam epitaxy (MBE), chemical beam epitaxy (CBE) and atomic layer epitaxy (ALE), etc. Depending in implementation, epitaxial processes may involve a variety of complex interactions of different materials, often extant in multiple phases, e.g., gas, liquid, and/or solid phases, that may take place in a specialized chamber for growing epitaxial layers, one layer at a time (e.g., a single layer of atoms or molecules, referred to as a monolayer), over the substrate. In broad terms, an epitaxial process may include the following steps and/or phenomena: transport of reactants to the substrate in a reaction chamber, diffusion of reactants to substrate surface, adsorption of reactants on substrate, surface processes such as reaction and adlayer incorporation, desorption of products and/or byproducts, transfer of products/byproducts to main transport medium (e.g., gas), and exhausting/removal of gases and other byproducts away from the reaction chamber.

Epitaxial films doped with n-type dopants including Group VA elements (or, synonymously, Group 5A or simply Group V) are applied in the fabrication of many IC devices as N-P-N and P-N-P junctions are fundamental to semiconductor device design and operation. Fabrication processes used to produce such epitaxial films rely upon the use of appropriate n-type source precursor molecules, which generally comprise Group V hydrides in the manufacture of a variety of IC products, including high volume manufacturing (HVM) process flows deployed in advanced technology nodes. Arsenic (As) and Phosphorus (P) are the most common n-type dopants that are usually incorporated into epitaxial films using arsine (AsH₃) and phosphine (PH₃) gas sources as precursors in concentrations ranging from the ppm range (typically diluted in H₂) to 100% pure form.

It is known that Group 5A hydrides, e.g., NH₃ (ammonia), PH₃ (phosphine), AsH₃ (arsine) and SbH₃ (stibine) are toxic to humans. Of particular importance are arsine and phosphine, both generally colorless and applied in gaseous form, which can cause various ailments depending on the duration of exposure and concentrations involved. Arsine is an odorless gas known to cause massive hemolysis, leading to anemia, jaundice, and hemoglobinuric renal failure, among other conditions. Phosphine, a flammable gas with a fish- or garlic-like odor, is known to cause restlessness and fatigue, disturbances of speech, vision, and gait, nausea, abdominal pain, vomiting and diarrhea, headache, thirst and chills. In more severe cases, respiratory ailments may include dyspnea, tightness of the chest and delayed-onset pulmonary edema, which may be followed by seizures and coma, and eventually death from heart failure. In general, the intensity and length of hydride exposure, combined with any premorbid conditions of the person exposed, may contribute to the time of onset and the severity of illness.

As both arsine and phosphine are highly toxic, various measures are taken in the semiconductor manufacturing industry to provide safety for personnel in IC fabrication plants and facilities, also referred to as foundries. Safeguards typically employed in a foundry may include specialized gas cabinets that are exhausted to appropriate facilities and sensitive detectors configured to monitor for the release of the toxic gases, high integrity gas distribution systems with sensitive monitoring at potential leak points contained within the enclosures, and general monitoring for trace quantities of AsH₃ and PH₃ within the fabrication clean room environment, among others. Such measures have been proven adequate for the safe use of n-type dopant gases in most scenarios, especially where the integrity of atmospheric barrier is maintained throughout a fabrication stage. However, there are situations where another source of the gases exists that is often overlooked—the wafers that have epitaxial films doped with As and/or P themselves, post processing, that may need to be carried in specialized wafer containers to additional fabrication stages for further processing.

Without limitation, it is postulated here for purposes of the present disclosure that epitaxial film growth processes involving the use of AsH₃ and PH₃ precursors generally result in surface segregation of dopant species (e.g., P and As) during the growth process. It is further postulated that the segregated dopant species may exist in an unincorporated form, e.g., not bound in the Si crystal lattice as interstitial dopants or as substitutional species in the lattice structure, whereby the dopant species may “float” to a top surface of the epitaxial layer as it is grown. Under certain conditions, the floating dopant species, also referred to as elemental dopant species, may form a surface-segregated layer (SSL) over the epitaxial layer, where the SSL may comprise one or a few monolayers consisting essentially of the dopant species not bound in a lattice structure. In contrast, the layers of n-doped films beneath the SSL contain P and As atoms that are formally bonded into the film crystalline structure (e.g., in covalent bonds) or incorporated interstitially before becoming available as electrically active dopants. Whereas the processing conditions in a reaction chamber are rigorously controlled to minimize ambient oxygen (O₂) and moisture (H₂O) in order not only that high quality crystalline materials can be grown during the epitaxial film growth process but also to reduce the risk of gas evolution reactions that can cause unintended release of arsine/phosphine gases. However, the presence of unincorporated dopants in an SSL film over the epitaxial layer continues to pose the threat of arsine/phosphine evolution (e.g., as outgassing) when the processed wafers are subsequently exposed to ambient conditions including O₂ and H₂O. The situation becomes even more complex and potentially hazardous where patterned wafers are involved and blanket film growth (non-selective epitaxy) is utilized because non-single crystalline materials with higher surface area relative to single crystal surfaces can result in SSLs having higher surface concentrations of unincorporated dopants that can outgas more readily.

Although gas evolution reactions involving doped epitaxial films can be complex, it is postulated here without limitation that such reactions may include oxidation and surface kinematics of the SSL films when exposed to moisturized air, where the unincorporated dopants may react with water (H₂O) to form harmful gaseous byproducts. Depending on the surface coverage of As and P species and the surface areas of the wafers involved, this outgassing can result in the buildup of AsH₃ and/or PH₃ in wafer carriers deployed to transport processed wafers throughout the fab manufacturing environment (e.g., “FOUPs” or “Front Opening Unified Pods”), thereby resulting in potentially hazardous situations at different foundry locations, particularly in HVM manufacturing facilities where the wafer throughput is very high.

Some baseline practices for handling the generation of AsH₃ and PH₃ in HVM environments include the use of inert ambient gases (typically N₂) in the wafer handling operations that transfer the processed n-type epitaxial wafers into the FOUPs, maintaining the FOUPs under an N₂ environment to prevent or slow down oxidation, and controlling additional oxidation reactions in specialized equipment configured to remove the toxic gases for proper and safe abatement. Although effective, such approaches require extensive infrastructure to implement and additional logistical controls related to the status of wafers post-epitaxy processing, thereby adding significant cost to the overall manufacturing process. Some examples may also use oxide “capping layers” over the doped epitaxial layers to mitigate the hazard of dopant hydride evolution. Whereas capping layers of intrinsic silicon and silicon dioxide may be effective, they add extra layers to the top surfaces of the intentionally doped epi layers, which may not be consistent with device requirements and/or performance. Further, the use of oxide capping layers requires the transportation of the processed wafers to a separate tool to perform the oxidation and thus necessitates additional safeguards during transport, similar to the concerns mentioned previously.

Examples of the present disclosure recognize these and related challenges and accordingly provide a technical solution for fabricating IC devices including doped epitaxial layers where a variety of post-epitaxy removal processes are provided for suppressing, reducing and/or eliminating, or otherwise mitigating the risk of dopant hydride evolution in a semiconductor fab environment. Depending on implementation, examples herein may include several classes of removal processes, e.g., either in a same reaction chamber or in a same tool used for epitaxy processing, where selective or non-selective etch operations may be implemented for removing an SSL from the doped epitaxy layer. Some examples may also include one or more post-removal surface modulation (PRSM) treatment options to condition the doped epitaxy layer in order to ameliorate any undesirable effects caused by and/or remaining after the removal operations as will be set forth in detail further below. While such examples and variations may be expected to abate the incidence of noxious gas evolution in a fab environment without significantly adding to the costs, in addition to potentially reducing manufacturing defects that could otherwise reduce yields, reliability or electrical performance of a product, no particular result is a requirement of the present disclosure unless explicitly recited in a particular claim.

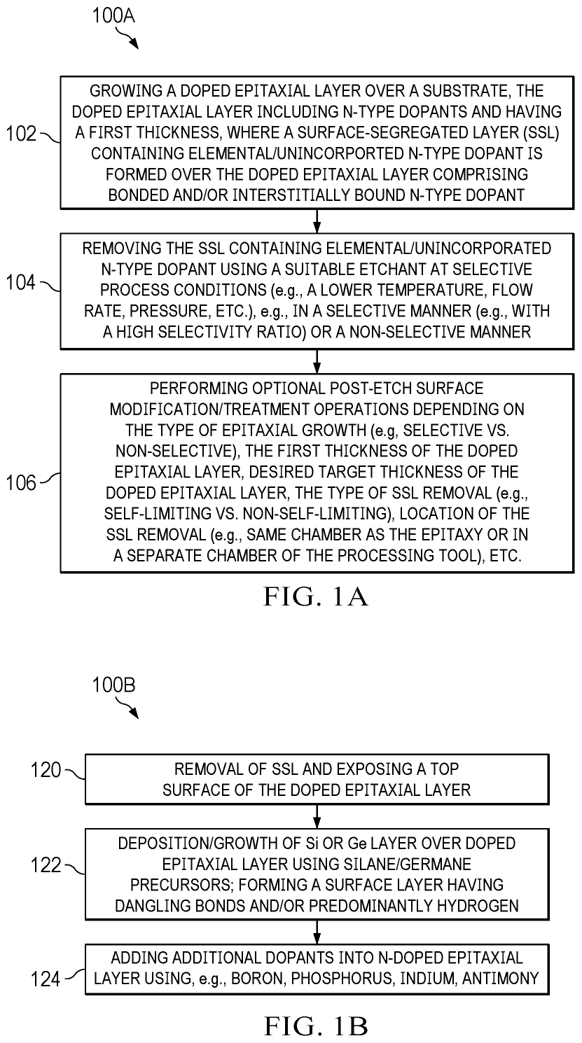

Turning to FIGS. 1A and 1B, depicted therein are flowcharts of an IC fabrication method where the illustrated steps, blocks, acts or operations may be combined in a number of ways according to some examples of the present disclosure. Example method 100A may commence with growing a doped epitaxial layer (or “epi layer” for short) over a substrate placed in a semiconductor process tool's working volume or reactor chamber, where the doped epitaxial layer may include n-type dopants, as set forth at block 102. As previously noted, the doped epitaxial layer may be formed using a variety of epitaxial processes and/or techniques, without limitation. Depending on implementation, the substrate may comprise a semiconductor substrate having a particular crystallographic orientation, and may comprise any suitable semiconductor material, e.g., suitably doped silicon as substrate material in some arrangements. In additional and/or alternative examples, other semiconductor materials such as, Ge, SiGe, GaAs, SiC, GaN, other Group III-V materials, etc., may be used as a substrate in some implementations, where one or more doped epitaxial layers or single-crystal layers may be formed or provided in some arrangements. In further variations, the substrate may comprise a monocrystalline material, a polycrystalline material, an amorphous material, a, a silicon-on-insulator (SOI) material, or a dielectric material. In some arrangements, the doped epi layer may be grown as a homoepitaxy layer or as a heteroepitaxy layer, where either selective epitaxial growth (SEG) process (also referred to as selective area epitaxy or SAE) or non-selective epitaxial growth processes may be used.

Depending on implementation, the doped epi layer may have a first thickness (e.g., on the order of tens or hundreds of nanometers), which may be reduced to a second thickness in some arrangements, as will be seen further below. The doped epi layer may have a surface-segregated layer (SSL), which may comprise one or more monolayers of unincorporated dopant species, e.g., As, P, etc., as noted previously. At block 104, the SSL film containing n-type dopants may be removed using a suitable etchant at selective process conditions (e.g., selective temperatures and pressures, flow rates of reactants, etchant compositions and selectivity rates, etc.). Depending on implementation, SSL removal may be performed in a selective manner (so as not to substantially etch the doped epitaxial layer and/or the substrate material (e.g., with a high selectivity ratio)) or a non-selective manner (which may remove at least a portion of the doped epi layer, e.g., more than 1% of the material in some arrangements). As will be seen further below, a variety of halogen-based chemistries may be provided for purposes of examples herein, which may be deployed in-situ, e.g., in a same reactor chamber or working volume and/or in a same cluster fabrication tool (e.g., in a different working volume of the tool) so as not to vitiate the integrity of the atmosphere barrier with respect to the epi layer growth and subsequent SSL removal. At block 106, one or more optional post-etch/removal surface modification/modulation (PRSM) treatment operations may be performed depending on the type of epitaxial growth (e.g., selective vs. non-selective), initial thickness of the doped epitaxial layer, desired target thickness of the doped epitaxial layer, the type of halogen-based etch used for SSL removal (e.g., self-limiting vs. non-self-limiting), situs of the SSL removal (e.g., same reaction chamber vs. same processing tool), etc.

FIG. 1B depicts additional steps of a method 100B that may be combined with at least a portion of the foregoing processes according to some examples herein. At block 120, an SSL formed over a doped epitaxial layer may be removed in accordance with a variety of in-situ etch flows, thereby exposing a top surface of the doped epitaxial layer. In one arrangement, a surface conditioning layer of silicon and/or germanium may be formed over the top surface of the doped epitaxial layer (block 122), where suitable silane/germane precursors may be used. Additionally and/or alternatively, several variations of surface conditioning may be implemented according to some examples herein as will be set forth further below. At block 124, additional dopants may be added (optionally) into the doped epitaxial layer, with a surface conditioning layer or without, where the additional dopants may include boron, phosphorus, indium, antimony, and/or any combination thereof, without limitation.

Several example SSL removal processes and optional surface modulation/modification treatments will now be set forth in additional detail below by way of illustration without any limitation as well as without any significance as to the order or priority in the following description unless otherwise specifically noted. In one arrangement, an example removal SSL process may be implemented after a desired film thickness of the doped epitaxial layer has been achieved, which may be determined using suitable in-situ metrological equipment such as ellipsometry configured to operate with the epitaxy chamber, thereby advantageously overcoming the safety concerns raised by post-epitaxy dopant hydride evolution. Further, examples herein may be implemented without the use of oxide capping layers, thus reducing and/or eliminating the safety risks without compromising the device design. In some examples, the dopant species in an SSL may be removed using an in-situ etching reaction as previously set forth. In some forms of this arrangement, the required etchant source(s) may already be provided as a part of the reactor system. Accordingly, no additional hardware components or gas sources need to be added to the reactor system.

In another example of the present disclosure, multiple steps may be employed to reduce and/or eliminate the surface dopant species through an in-situ etching reaction, followed by the reaction of the post-etch surface with a silane source precursor (SiₙH₂ₙ₊₂) and/or a germane source precursor (GeₙH₂ₙ₊₂) for surface conditioning as previously mentioned. In a variation of this example, where a halogen-based chemistry is used for etching, such surface conditioning or reconditioning may be employed to reduce and/or eliminate the surface layer of chemisorbed halogen(s) that may be produced through the etch process, thereby mitigating the risk of HX evolution (where X is a halogen) upon subsequent exposure to air. In some arrangements, germane source precursors may be preferred so as to enable a lower temperature reaction regime for removing the halogen surface layer that may be generated as a byproduct of the SSL etching. In some arrangements, the in-situ etching reaction may be configured as a self-limiting process (e.g., a selective etching process), for instance, through the choice of etchant species and/or in-situ etch process conditions. By way of illustration, the selectivity of an SSL etching reaction may be in on the order of hundreds- or thousands-to-one, such that the selected etchants may remove the SSL material much more readily than the doped epitaxial material or the substrate. In such a regime, the SSL etching reaction may be configured to cause essentially no removal of the doped epitaxial material.

In some arrangements, the reaction of the silane and/or germane source precursor(s) for surface (re) conditioning may also be configured as a self-limiting process or a non-self-limiting process through the selection of the silane and/or germane source precursor(s) and the subsequent reaction conditions. For purposes of some examples, it is postulated that modification/modulation of the top surface of the initially grown film (exposed after the removal of the SSL layer of the unincorporated dopants) using silane and/or germane source deposition precursors may result in the formation of a surface layer that is predominantly hydrogen and/or dangling bonds (depending on the temperature of the surface modification step) prior to the unloading of the wafer(s) from the reactor chamber or the clustered chamber depending on the tool configuration. Depending on the process conditions, the hydrogen- or dangling-bond surface layer may operate to mask the underlying n-type dopants during the formation of a native oxide over the top surface of the doped epitaxial layer when exposed to air. Whereas the surface conditioning layers based on Si/Ge may be undoped in some arrangements, additional dopants may be added using appropriate dopant source precursors in some arrangements as previously noted, where the dopant concentrations may range from 1×10¹⁵ atoms/cm³ to 1×10²¹ atoms/cm³ in some examples.

Suitable etchant sources for SSL removal may include, without limitation, halogen-containing gases and/or vapors that are compatible with epitaxial growth chambers and/or cluster fabrication tools. Depending on implementation, the halogen-based etchants may include iodine (I), bromine (Br) and chlorine (Cl), with chlorine being preferred in some examples. Fluorine (F) may also be considered to be within the scope of the present disclosure but is generally less preferred because epitaxial growth chambers used for silicon-containing epitaxial film growth generally comprise quartz (SiO₂) components that can be attacked by fluorine. Suitable halogen-containing gases and/or vapors may include, without limitation, any volatile halogen-containing source that can be delivered to the reactor chamber and that can be thermally activated to drive the in-situ etching reaction of the n-type dopant surface layers formed during/after the epitaxial film growth. In some arrangements, halogen-containing gases and/or vapors may include, without limitation, X₂ where X═I, Br, Cl and combinations thereof. In some arrangements, hydrogenated halogens may also be used as etchants, e.g., having a composition of HX where X═I, Br, Cl and combinations thereof. In some arrangements, the etchants may comprise saturated alkanes and/or analogs thereof having a composition of MₙZ₂ₙ₊₂ where M=C, Si and/or Ge or combinations thereof and Z═I, Br, Cl or H and combinations thereof, without limitation. Combinations of any of the foregoing chemistries are also within the scope of the present disclosure. Further, any of the preceding gases and/or vapors may be used in pure or diluted forms and/or mixtures, depending on implementation. By way of example, a halogen-containing gas may comprise Cl₂ delivered as a mixture including a carrier gas, where the carrier gas may comprise H₂, N₂, a noble gas such as helium (He), neon (Ne), argon (Ar) and/or xenon (Xe) and/or any suitable combinations thereof.

A variety of suitable etching process conditions may be employed, e.g., largely dependent on the nature of the etchant(s) to be used and the degree of selectivity of the etching process. As previously noted, an example SSL etching process may be configured to be highly selective, e.g., with respect to the underlying doped epitaxial film. In some arrangements, selective etching of the surface-segregated dopant layer can be achieved through process optimization (e.g., as a self-limiting etch process) where different conditions may be modulated such as the temperature of the etching process, the flow rates and partial pressures of the etchant(s), the flow rates of any carrier gases co-introduced with the etchant(s) and the pressures at which etching reaction is conducted, etc.

In a specific example, HCl may be used as the etchant, where the n-type dopant is arsenic (As). In a first step, the epitaxial silicon film may be grown non-selectively with a doping concentration of about 1×10²¹ atoms/cm³ using a flow of about 200 standard cubic centimeters per minute (sccm) Si₂H₆ and a flow of about 500 sccm of AsH₃ (1% in H₂) source gases diluted in a flow of about 50 standard liters per minute (slm) H₂. The epitaxial growth may be conducted at a temperature of about 600° C. and a pressure of about 8 kilopascals (kPa) for a length of time sufficient to grow an epitaxial film that is about 30 nm thick. The As-doped epitaxial silicon film may have a segregated surface layer of As that results from As segregation during the epitaxial growth process. In a second step, the surface segregated As layer may be removed from the surface of the epitaxial film using an in-situ, thermal HCl etch conducted at the epitaxial film growth temperature (˜600° C.). The etch process may be conducted with a flow of about 300 sccm HCl diluted in a flow of about 50 slm of ultra-pure H₂ at a pressure of about 5300 Pa. The etch process may be continued for a time sufficient to substantially completely remove the surface segregated As layer from the top of the As-doped silicon film from the entire surface of the wafer, which in this non-limiting example is about 60 seconds.

In some examples, different modification/modulations may be used to optimize the process conditions to remove essentially all of the surface segregated As in a minimum amount of time. Because the etching process conditions can be centered below the temperature at which HCl can etch silicon, an example process may be configured to be self-limiting with respect to the epitaxial As-doped silicon that lies beneath the surface segregated As layer.

In a third step, the pressure in the reactor chamber may be increased to about 55 kPa with a flow of about 40 slm ultra-pure H₂ carrier gas while the temperature is decreased from about 600° C. to about 530° C. and allowed to stabilize for about 30 seconds. After the stabilization time has elapsed, a flow of about 400 sccm of SiH₄ is introduced into the reactor system while continuing to flow the ultra-pure H₂ carrier gas (at about 40 slm) for a period of time sufficient to generate approximately one monolayer of chemisorbed SiH₃ groups on the surface of the As-doped epitaxial silicon film, which in this non-limiting example is about 12 seconds. In some examples, additional modulations may be used to optimize the process conditions to deposit essentially one monolayer of surface adsorbed SiH₃ groups in a minimum amount of time. The reactor may then be returned to standard unload conditions, whereupon the wafer(s) may be unloaded from the chamber and transferred through various transfer compartments, via chambers, etc. of the cluster tool platform in a transfer sequence until the wafer(s) are placed in a batch load lock of the cluster tool platform.

In another arrangement, an example SSL etching reaction may be carried out in a separate chamber that is attached to the cluster tool platform in a suitable configuration (e.g., in-situ tool etch in contrast to in-situ chamber etch), which also avoids exposure of the wafer surfaces to external ambient conditions prior to performing the etching reaction(s) to remove the SSL dopant species from the surfaces of the wafers. Depending on implementation, this arrangement may offer the advantage of a reduced impact on overall throughput and cost of ownership. Additionally, it enables the use of other types of SSL etch processes and/or etchants, e.g., fluorine-containing etchant species, plasma type etching processes, etc., based on appropriate materials selection and/or chamber design. In an example implementation, a dedicated chamber can be configured to use thermal and/or plasma etching in order to remove the SSL material including unincorporated dopants. Plasma processes contemplated within the scope of the present disclosure may include in-situ plasma, remote plasma and/or combinations thereof. In some arrangements, the appropriate etchant(s), carrier gases and deposition precursors may be the same as those set forth about for the in-situ chamber etch schemes. In a specific example involving the use of a dedicated chamber clustered with the epitaxial reactor chamber(s), a plasma process with H₂ used as the etchant source gas may be employed to remove the surface segregated n-type dopant layer and provide hydrogen-based surface termination/passivation of the top surface of the initially grown n-type doped epitaxial film. Additional modulations may be undertaken to identify the process conditions that yield removal of substantially all of the segregated n-type dopant layer and provide appropriate surface termination/passivation of the top surface of the doped epitaxial film with or without substantially changing the thickness of the initially grown epitaxial film (e.g., based on selectivity) similar to the other SSL etch processes described previously.

Set forth below are some generalized chemical reactions that may be representative of etching processes employed for purposes of some examples herein:
(A) Halogen-containing etchant+segregated n-type surface layer→{n-type}X₃ (g) at the growth temperature (T), or at a different T (non-self-limiting), X=halogen;
(B) Halogen-containing etchant+segregated n-type surface layer→{n-type}X₃ (g) at the growth T, or at a different T (having a high selectivity with respect to the n-type doped film significantly, e.g., self-limiting), X=halogen;
(C) Reaction (A)+silane and/or germane source precursor(s) at in-situ etch reaction temperature (self-limiting or non-self-limiting growth in combination with non-self-limiting halogen etch); and
(D) Reaction (B)+silane and/or germane source precursor(s) at in-situ etch reaction temperature (self-limiting or non-self-limiting growth in combination with self-limiting halogen etch).

As previously noted, suitable etch conditions may depend on the type of etching process (thermal and/or plasma, where example plasma processes can involve in-situ or remote plasma sources and different species), the etchant species selected and whether the process is to be self-limiting (e.g., with various degrees of selectivity) with regard to the undesirable SSL materials vs. the beneficial doped epitaxial films. In some non-limiting examples involving chlorine-based etchants, the temperature may be maintained at less than approximately 750° C. for self-limiting etch reactions, whereas for non-self-limiting etch reactions, the temperature may be more than about 750° C. For plasma processes, the temperature may range from −50° C. to 600° C. in some implementations. The etch process pressures may range from 100 kPa to about 145 kPa. Etchant flow rates may range from 1 sccm to about 20 slm and carrier gas flow rate(s) may range from 0 sccm to about 200 slm, regardless of the type of etchant gas mixtures and/or carrier gas mixtures that may be used in some example implementations.

In some arrangements involving plasma, an additional etchant source within the scope of the present disclosure may comprise ultra-high purity H₂ (99.9998% ALPHAGAZ™ 2 Grade), with the targeted etch byproducts being {n-type dopant}H₃ (g).

In general, different etch processes may be optimized for different dopant applications and reactor/tool configurations in accordance with the teachings herein. In some particular examples, the etch processes may be configured or otherwise optimized such that the byproduct(s) of the etch reactions utilized to remove the SSL dopant species are volatile species with low melting and/or boiling points to ensure that they are efficiently removed from the reactor chamber and transported to the exhaust pump and associated abatement systems already incorporated as a part of the reactor/tool system. Some representative etch byproducts and their properties are illustrated in the table below where some examples may comprise compounds that may decompose at temperatures before reaching their normal boiling points:

| Compound | Melting Point (° C.) | Boiling Point (° C.) |
|---|---|---|
| AsF₃ | −8.5 | 60.4 |
| AsCl₃ | 16.2 | 130.2 |
| AsBr₃ | 31.1 | 221 |
| AsI₃ | 146 | 403 |
| PF₃ | −151.5 | −101.8 |
| PCl₃ | −93.6 | 76.1 |
| PB₃ | −41.5 | 173.2 |
| PI₃ | 61.2 | 200 (decompose) |

In a non-limiting example, an IC fabrication method according to the teachings herein may comprise the following steps:
(A) Complete epitaxial growth process at the desired thickness and doping concentration target;
(B) If necessary, adjust temperature and flow conditions to enable a self-limiting in-situ etch of the SSL layer containing unincorporated/elemental n-type dopant species, e.g., by using HCl (for etching the SSL/elemental layer down to film surface and terminating surface with H and Cl);
(C) If necessary, adjust temperature and flow conditions to enable a self-limiting removal of the chemisorbed Cl layer generated during the etch without substantially changing the film thickness by introducing silane and/or germane source deposition precursor(s) and provide a hydrogen-based surface termination to replace an n-type dopant top surface; and
(D) Remove/unload wafer from the tool with reduced or little risk of AsH₃ and/or PH₃ gas evolution.

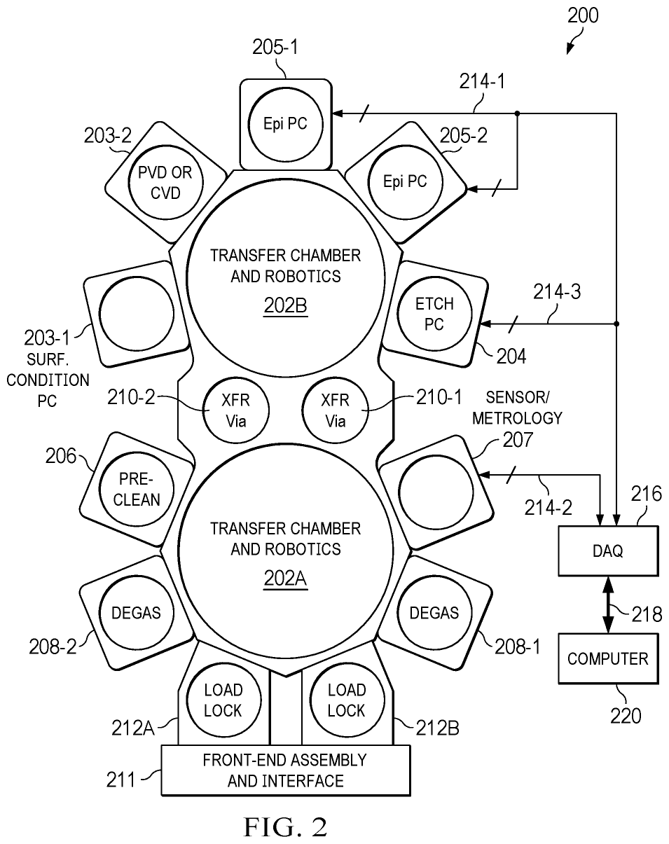

Turning now to FIG. 2, depicted therein is a general schematic configuration of a wafer processing tool 200 operable for epitaxial processing and suppressing dopant hydride evolution that may be deployed in association with one or more process stages of a wafer fabrication flow according to some examples of the present disclosure. By way of illustration, the processing tool 200 may be implemented as a configurable tool for deployment at a process stage where a doped epitaxial layer may be formed over suitable substrates using any known or heretofore unknown epitaxial techniques in one or more reactor chambers or process chambers 205-1, 205-2. In some arrangements, chambers 205-1 and/or 205-2 may be adapted as working volumes to perform a variety of SSL etch operations as described above (e.g., designated herein as in-situ chamber etch operations). Further, the processing tool 200 may additionally and/or alternatively include one or more dedicated chambers or working volumes configured to perform one or more SSL etch operations within the tool, e.g., designated herein as in-situ tool etch operations, according to some examples.

In some arrangements, the processing tool 200 may be configured as a multifunctional tooling system, also referred to as a cluster tool system, that allows for the automatic transfer of semiconductor process wafers (also referred to as semiconductor wafers, process wafers, or simply wafers in some examples) between different reactor chambers configured to effectuate different processes, or to process similar layers in parallel, without exposing the wafers to air in between the process steps. In such arrangements, accordingly, one or more process chambers may be provided that are operable as respective working volumes, each adapted to effectuate corresponding process steps, operations and/or recipes associated with a broad range of wafer fabrication technologies including but not limited to physical vapor deposition (PVD), chemical vapor deposition (CVD) including atomic layer deposition (ALD) and plasma enhanced CVD (PECVD), etc. as well as rapid thermal processing (RTP) and rapid thermal annealing (RTA) stages used for dopant activation, pre-/post-clean processes, degas operations, surface conditioning/modulation, and the like. As illustrated in FIG. 2, example process chambers 203-1, 203-2, pre-clean chamber(s) 206 (e.g., using RF or plasma), and degas chambers 208-1, 208-2, are representative of such chambers that may be provided in processing tool 200, e.g. a cluster tool system. In some arrangements, various properties and characteristics associated with semiconductor process wafers such as film thicknesses, sheet resistances, temperature-dependency of resistances, etc., may need to be monitored and controlled during a processing stage. Accordingly, one or more sensor/metrology chambers 207 may also be provided as part of an example cluster tool system such as the processing tool 200.

Depending on implementation, the processing tool 200 may be configured to include multiple main chambers 202A, 202B to which the foregoing process chambers and sensing/metrology chambers may be detachably coupled. In one arrangement, a first main chamber, e.g., main chamber 202A, may be configured as a buffer chamber having robotic wafer handling capability for facilitating loading and/or unloading of semiconductor process wafers using load lock chambers 212A and 212B coupled to a front-end assembly and interface 211 that is adapted to cooperate with specialized wafer carrier systems such as FOUPs. Main chamber 202A may also operate as a transfer chamber for facilitating the transfer for process wafers between different process chambers coupled thereto. Likewise, a second main chamber, e.g., main chamber 202B, may also be configured as a transfer chamber that may also include a robotic wafer handling system for facilitating the transfer of wafers from one process chamber to another depending on the process flow. In some examples, robotic wafer handling systems may comprise a robotic arm operative to rotate around vertical and horizontal axes as well as travel on any plane in a 3D space enclosed by main chambers 202A, 202B. One or more transfer vias or conduits 210-1, 210-2 may be coupled between the main chambers 202A and 202B for facilitating the transfer for process wafers between the two main chambers 202A and 202B. In some arrangements, appropriate cooling chambers may be provided (not specifically shown in this Figure) for cooling/regulating the temperatures of the process wafers prior to or after a processing stage.

Depending on implementation and/or process flow requirements, various processing chambers, load lock chambers, sensor/metrology chamber(s), any additional/expansion chambers, as well as main chambers 202A, 202B may be (de) pressurized to varying levels using appropriate gases (e.g., Argon, Nitrogen, etc.) in conjunction with one or more servomechanical vacuum pumps and associated hardware (e.g., cryo pumps, turbo pumps, rotary vane pumps, etc., not specifically shown in this Figure). Suitable mechanical coupling between main chamber 202A, 202B and other chambers may therefore be provided in order to facilitate chamber detachability while maintaining vacuum integrity during operation.

In one arrangement, suitable communication interfaces may be provided with various process chambers as well as sensor/metrology chambers, which may be coupled to a data acquisition (DAQ) unit 216 for collecting sensor data and transmitting the data to a host computer 220 using any known or heretofore unknown data collection/transmission protocols via a local network and/or a remote network 218. By way of example, interfaces 214-1, 214-2 and 214-3 are provided with respect to the epitaxy chambers 205-1/205-2, the sensor/metrology chamber 207, and the SSL etch chamber 204, and respectively. In addition to data gathering, monitoring and processing, the host computer 220 may be configured to execute appropriate process software or programs for effectuating and/or controlling various process recipes, e.g., with respect to doped epitaxial growth processes, SSL removal processes, post-removal surface conditioning, and the like, according to the examples herein. Depending on implementation, the host computer 220 may be deployed as a local or remote host, or at a cloud-based data center associated with an IC fabrication facility, which may include one or more processors operating under program control to effectuate sensing processes and process recipes, data analysis, report generation, etc.

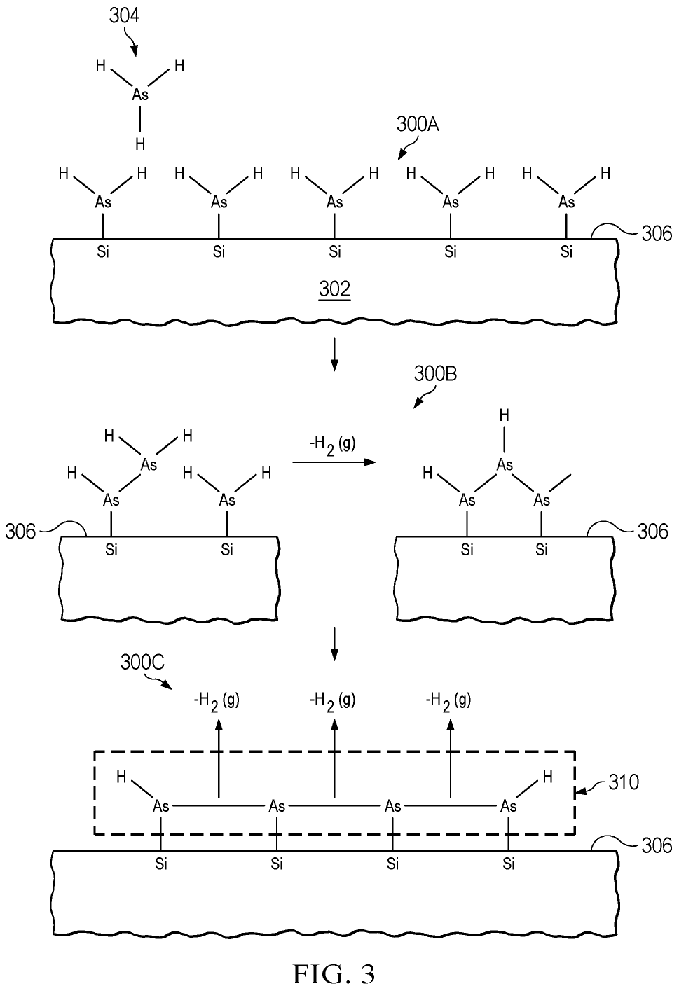

FIGS. 3A-3C depict generalized chemical reactions illustrating the formation of a surface-segregated layer (SSL) including elemental or unincorporated dopants that may be generated in a doped epitaxy process in some examples. Reference numeral 300A is representative of the application of dopant precursor molecules 304, e.g., AsH₃, on a surface 306 of a substrate 302. In some arrangements, the dopants may be introduced into the substrate at concentrations greater than a solid solubility parameter of the substrate. Surface reaction kinetics such as chemisorption, which is a type of adsorption, may initially take place near the surface 306, where adjacent dopant precursors in localized regions of the substrate 302 may form bonds between the dopant atoms (e.g., As—As bonds) through elimination of hydrogen, as represented by reference number 300B. This process may continue to take place throughout the duration of the epitaxial growth whereby successive chemisorption kinetics may give rise to localized “surface clusters” 310 of dopant atoms that are not incorporated into the underlying substrate lattice. Depending on the dopant concentrations and epitaxial process conditions involved, the unincorporated dopant atom clusters 310 may form a contiguous sheet or a layer over a substantial portion of the growing/grown epitaxial layer formed over the substrate, thereby operating as an SSL capable of causing harmful outgassing as set forth previously in the present disclosure. In a fab environment, such surface clusters and/or segregated layers over a doped epitaxial layer may be detected by suitable instrumentation such as energy dispersive X-ray (EDX) equipment.

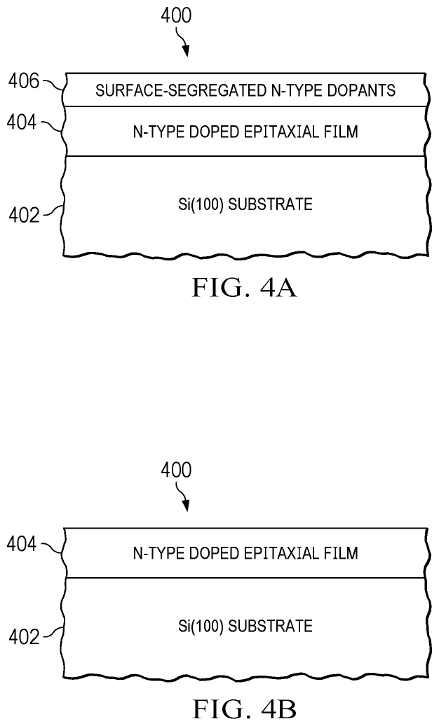

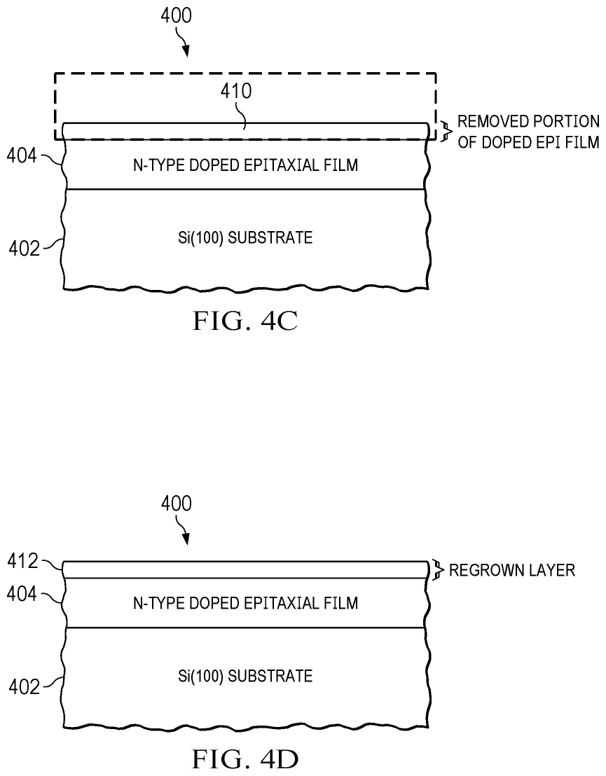

FIGS. 4A-4D depict cross-sectional view of an IC device at various stages of formation according to some examples of the present disclosure where dopant hydride evolution may be suppressed in accordance with the teachings herein. Reference number 400 in FIG. 4A refers to an IC device comprising a semiconductor substrate 402, e.g., a silicon substrate having a suitable crystallographic orientation such as [100], [110], [111], etc., without limitation. As previously set forth, the IC device 400 may be representative of an IC at an early fabrication stage of a flow for manufacturing any type of IC product that may be based on a variety of semiconductor technologies such as bipolar junction transistor (BJT) technologies, heterojunction bipolar transistor (HBT) technologies, metal oxide semiconductor (MOS) technologies, complementary metal oxide semiconductor (CMOS) technologies, double-diffused metal oxide semiconductor (DMOS) technologies, etc., including analog, digital and/or mixed signal device designs. In some examples, a combination of semiconductor technologies may be implemented, wherein different technologies suitable for respective types of product design may be integrated within the same chip or IC device, e.g., linear BiCMOS or LBC (a bipolar-CMOS combination technology where bipolar technology may be used for analog functions and CMOS may be used for digital logic design), BCD (a bipolar-CMOS-DMOS combination technology where DMOS may be integrated within the IC device for power and high-voltage portions that also has analog and digital portions), and the like. Accordingly, without being limited to a particular implementation, the semiconductor substrate 402 may comprise a portion of a semiconductor process wafer, e.g., an IC die, that may be at a stage without any patterning or at a stage having patterned structures or layers thereon where the IC device 400 may have been processed to include to any combination of epitaxial layers, buried layers, laterally diffused extensions, N-wells, P-wells, deep wells, shallow wells, reduced surface field (RESURF) layers formed over the dielectric layers of SOI substrates, etc. Further, the example semiconductor substrate 402 may include various isolation structures for dielectrically isolating the constituent layers, regions, well structures, etc., using a variety of isolation techniques, e.g., shallow trench isolation (STI), local oxidation of silicon (LOCOS), etc. that may be formed during the process flow, which are not explicitly shown in the Figures herein.

An n-doped epitaxial film 404 of a suitable thickness may be formed over the substrate 402 using any epitaxy technology, where the growth may be selective or non-selective. An SSL 406 having a thickness of one or a few monolayers and including surface-segregated dopants (e.g., As, P, etc.) that are unincorporated in the doped epitaxial film 404 may be formed over the doped epitaxial film 404 as previously set forth. An example in-situ etch process may be performed, e.g., in the same epitaxial reactor chamber, using a halogen-containing gas and/or vapor, with or without a carrier gas, whereby the SSL 406 may be removed from the IC device 400 as illustrated in FIG. 4B. As previously described, the etching process may be a non-limiting process (e.g., the process may also etch the doped epitaxial film 404, thereby removing a top portion thereof) or a self-limiting process (e.g., having a high degree of selectivity, where the process may not substantially etch the doped epitaxial film 404). Some generalized chemical reaction mechanisms involving halogen-based etch chemistries as contemplated herein are set forth below:
(A) Using HCl (g) in H₂ (carrier gas):
   3HCl (g)+1 {SSL n-type dopant atom}→{n-type}Cl₃ (g)+H₂ (g)
(B) Using Cl₂ (g) in H₂ (carrier gas):
   3Cl₂ (g)+2 {SSL n-type dopant atoms}→2 {n-type}Cl₃ (g)

In some examples, Cl₂-etching may be performed at a lower temperature range (e.g., about 100° C. to 150° C. lower) than a temperature range used for the HCl-etching. Whereas the thickness of the doped epitaxial film 404 may not be substantially changed in a selective etch process, the initial thickness may be in a separate process after the SSL removal to a target thickness in some examples. Further, any surface chlorine remaining after the SSL removal may be removed by depositing Si and/or Ge in a post-etch deposition step using suitable precursors, e.g., silane/germane, as previously noted.

FIG. 4C illustrates another example where a non-selective etch may be configured to remove a portion 410 of the doped epitaxial film 404, where Cl₂-etching or HCl-etching may be implemented as noted above. FIG. 4D illustrates a subsequent stage where a secondary doped film 412 may be regrown over the initial doped epitaxial film 404 to obtain an overall target thickness in some examples. Depending on the type of dopant and/or the dopant concentration used in the secondary doped film 412, it is expected that the effects of toxic outgassing due to the secondary doped film 412 may be minimized. In some arrangements, a different n-type dopant (e.g., phosphorus) may be used instead of arsenic, which is more toxic than phosphorus, thereby mitigating the risk of the hydride evolution. In some arrangements, a lower concentration of dopant may be used in the secondary doped film 412 than in the initial doped epitaxial film 404 in order to minimize the risk. As previously noted, various (optional) post-removal surface modulation/modification treatments may be provided that may be integrated with any of the foregoing fabrication flows.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A method of fabricating an integrated circuit (IC), comprising:
placing a semiconductor substrate in a semiconductor process tool working volume;
forming a doped epitaxial layer over the semiconductor substrate, including forming a surface-segregated layer (SSL) including a dopant species unincorporated in the doped epitaxial layer;
removing the SSL; and
removing the semiconductor substrate from the working volume.

2. The method as recited in claim 1, wherein the SSL is removed by selectively etching the SSL with essentially no removal of the doped epitaxial layer.

3. The method as recited in claim 1, wherein the SSL is removed using a non-selective etch including removing a portion of the doped epitaxial layer.

4. The method as recited in claim 1, wherein the SSL is removed using a halogen-based etchant comprising at least one of iodine (I), chlorine (Cl), bromine (Br), and any combination thereof.

5. The method as recited in claim 1, wherein the SSL is removed using a hydrogenated halogen etchant comprising at least one of hydrogen iodide (HI), hydrogen chloride (HCl), hydrogen bromide (HBr), and any combination thereof.

6. The method as recited in claim 1, wherein the SSL is removed using an etchant comprising a saturated alkane or an analog thereof having MₙZ₂ₙ₊₂ composition, where M comprises at least one of C, Si, Ge and any combinations thereof and Z comprises at least one of I, Br, Cl, H and any combinations thereof.

7. The method as recited in claim 1, further comprising forming a surface conditioning layer over the doped epitaxial layer, the surface conditioning layer formed from at least one of a silane (SiₙH₂ₙ₊₂) precursor, a germane (GeₙH₂ₙ₊₂) precursor, and any combination thereof.

8. The method as recited in claim 7, wherein the surface conditioning layer is doped with at least one of boron (B), indium (In), phosphorous (P) and antimony (Sb).

9. The method as recited in claim 1, wherein the SSL is removed in an operation using the working volume used for forming the doped epitaxial layer.

10. The method as recited in claim 1, wherein the SSL is removed in an operation using a different working volume of the semiconductor process tool.

11. The method as recited in claim 1, wherein the doped epitaxial layer includes Group V dopant species.

12. An integrated circuit (IC), comprising:
a semiconductor substrate;
a doped epitaxial layer over the semiconductor substrate, the doped epitaxial layer having a first dopant concentration; and
a surface conditioning layer over the doped epitaxial layer, the surface conditioning layer comprising silicon or germanium having a second dopant concentration less than the first dopant concentration.

13. The IC as recited in claim 12, wherein the doped epitaxial layer includes Group V dopant species.

14. The IC as recited in claim 13, wherein the surface conditioning layer is doped with at least one of boron (B), indium (In), phosphorous (P) and antimony (Sb).

15. An integrated circuit (IC) fabrication tool, comprising:
at least one main chamber;
a first processing chamber coupled to the at least one main chamber, the first processing chamber configured to form a doped epitaxial layer over a semiconductor substrate; and
a second processing chamber coupled to the at least one main chamber, the second processing chamber configured to remove a surface-segregated layer (SSL) formed over the doped epitaxial layer.

16. The IC fabrication tool as recited in claim 15, wherein the first processing chamber is further configured to form a surface conditioning layer over the doped epitaxial layer after the SSL is removed, the surface conditioning layer comprising at least one of silicon and germanium.

17. The IC fabrication tool as recited in claim 15, wherein the second process chamber is configured to remove the SSL using an etchant in a selective etch or in a non-selective etch.

18. The IC fabrication tool as recited in claim 17, wherein the etchant comprises a halogen-based etchant including at least one of iodine (I), chlorine (Cl), bromine (Br), and any combination thereof.

19. The IC fabrication tool as recited in claim 17, wherein the etchant comprises a hydrogenated halogen etchant comprising at least one of hydrogen iodide (HI), hydrogen chloride (HCl), hydrogen bromide (HBr), and any combination thereof.

20. The IC fabrication tool as recited in claim 17, wherein the etchant comprises a saturated alkane or an analog thereof having MₙZ₂ₙ₊₂ composition, where M comprises at least one of C, Si, Ge and any combinations thereof and Z comprises at least one of I, Br, Cl, H and any combinations thereof.
